(19) United States
(12) Patent Application Publication
(10) Pub. No.: US 2010/0246256 A1
(43) Pub. Date: Sep. 30, 2010

(54) NONVOLATILE SEMICONDUCTOR MEMORY

(75) Inventor: Kenji SAWAMURA, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/748,743

(22) Filed: Mar. 29, 2010

(30) Foreign Application Priority Data
Mar. 30, 2009 (JP) 2009-082346

(51) Int. Cl. G11C 16/06

(52) U.S. Cl. 365/185.2

(57) ABSTRACT

A nonvolatile semiconductor memory includes: a lower semiconductor layer; a first cell string having a plurality of memory cells formed on the lower semiconductor layer; an upper semiconductor layer formed above the lower semiconductor layer; and a second cell string having a plurality of memory cells formed on the upper semiconductor layer. A memory cell formed on a crystal defect of the upper semiconductor layer among the plurality of memory cells that form the second cell string is operated as a dummy cell.

### CROSS-REFERENCE TO RELATED APPLICATIONS

This Application is based upon and claims the benefit of priority from the prior Japanese Patent Application No. P2009-82346, filed on Mar. 16, 2009; the entire contents of which are incorporated herein by reference.

### BACKGROUND OF THE INVENTION

1. Field of the Invention

The present invention relates to a nonvolatile semiconductor memory, and particularly, to a nonvolatile semiconductor memory having 3-Dimensionally arranged memory cells.

2. Description of Related Art

The following technique has been disclosed that achieves high integration of memory cells in a NAND-type nonvolatile memory (for example, Patent Document 1). In the technique, the memory cells are stacked to form a multilevel structure. This technique can reduce the bit cost of the NAND-type nonvolatile memory.

The following technique has been conceived that reduces fluctuation in an initial characteristic of a memory cell even when the memory cell is formed on a semiconductor layer having the crystal defect (for example, Patent Document 2). In this technique, a source/drain of the memory cell is disposed on the crystal defect. This technique enables an influence on characteristics of this memory cell to be suppressed, and thus enables the fluctuation in the initial characteristic of the memory cell to be reduced. However, the alignment of a source/drain of a memory cell with a crystal defect has been more difficult because of the advancement of miniaturization. For this reason, a channel of a memory cell is unintentionally formed on the crystal defect as in the related art, thereby increasing a possibility that the initial characteristic of the memory cell shows fluctuation.

### BRIEF SUMMARY OF THE INVENTION

According to an aspect of the present invention, an nonvolatile memory device can be provided, the nonvolatile memory device including: a lower semiconductor layer; a first cell string having a plurality of memory cells formed on the lower semiconductor layer; a upper semiconductor layer formed on the lower semiconductor layer with an interlayer insulating film interposed therebetween; and a second cell string having a plurality of memory cells formed on the upper semiconductor layer; wherein a memory cell formed on a crystal defect in the upper semiconductor layer is a dummy cell.

### BRIEF DESCRIPTION OF THE DRAWINGS

FIG. 1 is a plan view of a memory cell array of a NAND-type nonvolatile memory according to a first embodiment of the present invention;

FIG. 2 is a sectional view of a device in a direction of a bit line of the NAND-type nonvolatile memory according to the first embodiment of the present invention;

FIG. 3 is an equivalent circuit diagram of a cell string of the NAND-type nonvolatile memory according to the first embodiment of the present invention;

FIG. 4 is a chart showing conditions of write, read, and erase voltage of data in the NAND-type nonvolatile memory according to the first embodiment of the present invention;

FIG. 5 is a sectional view of a NAND-type nonvolatile memory according to a second embodiment of the present invention in a direction of a bit line;

FIG. 6 is a plan view of a memory cell array of a NAND-type nonvolatile memory according to a third embodiment of the present invention; and

FIG. 7 is a sectional view of a NAND-type nonvolatile memory according to the third embodiment of the present invention in a direction of a bit line.

### DETAILED DESCRIPTION OF THE INVENTION

Hereinafter, embodiments according to the present invention will be described with reference to the drawings.

### Embodiment 1

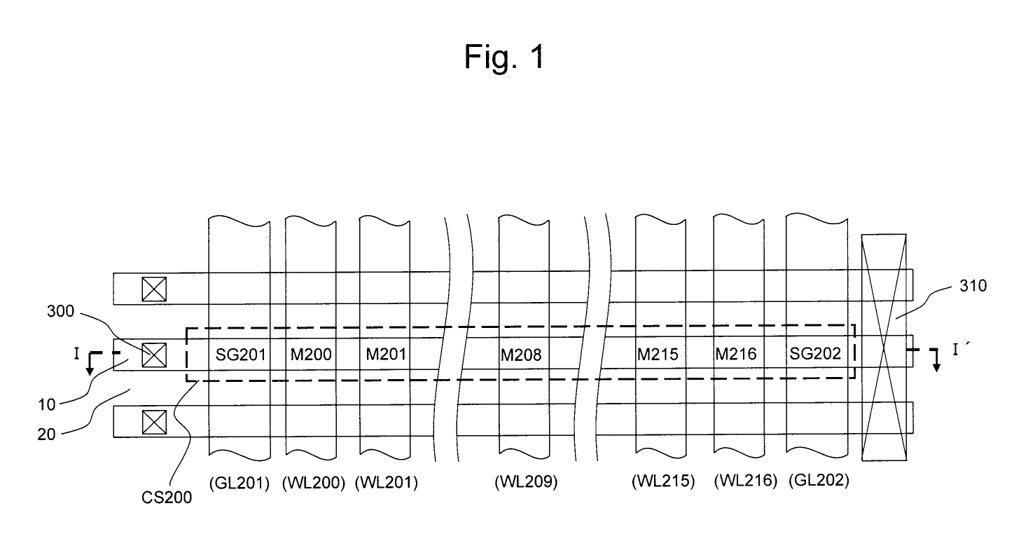

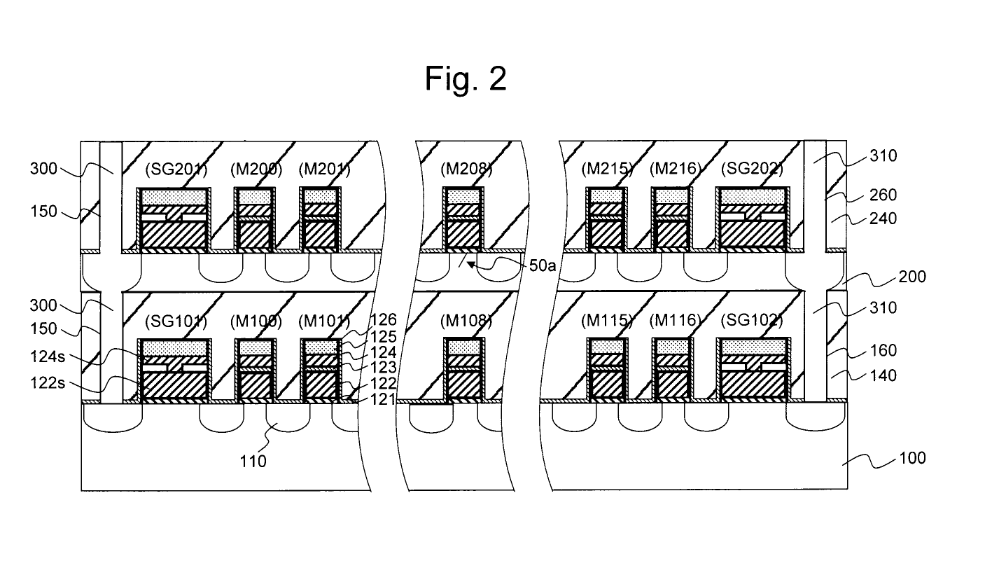

FIG. 1 is a plan view of a memory cell array of a NAND-type nonvolatile memory according to a first embodiment. FIG. 2 is a sectional view of the NAND-type nonvolatile memory according to the first embodiment in a direction of a bit line (a sectional view taken along the line I-I′ in FIG. 1).

First, with reference to FIG. 1, a planar structure of the NAND-type nonvolatile memory according to the embodiment will be described. The NAND-type nonvolatile memory according to the embodiment has a multilevel configuration of memory cells. FIG. 1 is a plan view of a memory cell array of an upper NAND-type nonvolatile memory. A lower NAND-type nonvolatile memory also has the same memory cell array planar structure as that of the upper NAND-type nonvolatile memory.

As shown in FIG. 1, the NAND-type nonvolatile memory according to the embodiment includes an element formation region 10 and an isolation region 20 alternately formed in belt shapes on a P type silicon layer. On each element formation region 10, a plurality of memory cells M200 to M216 are disposed in series. A selection gate transistor SG201 is disposed at one end of a series of the memory cells M200 to M216 disposed in series, and a selection gate transistor SG202 is disposed at the other end thereof. As described later, among the plurality of memory cells M200 to M216, a memory cell M208 disposed at a center operates as a dummy cell, which is not used as a data storage element. A cell string CS200 includes the plurality of memory cells M200 to M216 disposed in series on the element formation region 10 and the selection gate transistors SG201 and SG202.

The memory cells formed in adjacent element formation regions 10 are connected to each other by word lines WL200 to WL216. The selection transistors SG201 formed in adjacent element formation regions are connected to each other by a selection gate line GL201. Similarly, the selection transistors SG202 formed in adjacent element formation regions are connected to each other by a selection gate line GL202. A set of the cell string that shares the word lines WL200 to WL216 and the selection gate lines GL201 and GL202 forms one block serving as a unit of collective data erasure in the NAND-type nonvolatile memory.

A bit line plug 300 is formed at an outer side of the selection gate transistor SG201 of the cell string CS200, and a source line plug 310 is formed at an outer side of the selection gate transistor SG202. The bit line plug 300 and the source line plug 310 are respectively a bit line plug and a source line plug shared by a cell string CS100 formed in a lower semiconductor layer 100 and a cell string CS200 formed in an upper semiconductor layer 200, which will be described later.

Next, with reference to FIG. 2, a cross-sectional structure of the NAND-type nonvolatile memory according to the embodiment will be described. As shown in FIG. 2, the NAND-type nonvolatile memory according to the embodiment includes a lower semiconductor layer 100 and an upper semiconductor layer 200 formed on the lower semiconductor layer 100. An interlayer insulating film 140 is formed between the lower semiconductor layer 100 and the upper semiconductor layer 200. The lower semiconductor layer 100 and the upper semiconductor layer 200 correspond to the element formation region 10 shown in FIG. 1. The lower semiconductor layer 100 is formed of a P type silicon substrate. The upper semiconductor layer 200 is formed of a single crystal P type silicon layer. While a two-level NAND-type nonvolatile memory formed of the lower semiconductor layer 100 and the upper semiconductor layer 200 will be described in the embodiment, a similar configuration provides a similar effect also in a multilevel NAND-type nonvolatile memory having three or more levels.

On the lower semiconductor layer 100, a plurality of memory cells M100 to M116 are formed. As is well known, each memory cell has a laminated structure including a floating gate electrode 122 formed on the lower semiconductor layer 100 with a gate insulating film 121 interposed therebetween, a control gate electrode 124 formed on the floating gate electrode 122 with an intergate insulating film 123 interposed therebetween, and a silicide layer 125 formed on the control gate electrode 124. N type diffusion layers 110 are formed on both sides of the gate insulating film 121 in the lower semiconductor layer 100. A sidewall insulating film 126 is formed on a sidewall of a laminated structure body. The lower semiconductor layer 100 under the gate insulating film 121 serves as a channel of the memory cell.

The selection gate transistors SG101 and SG102 disposed at both ends of the series of the plurality of memory cells M100 to M116 have a laminated structure similar to that of the above-mentioned memory cell. A gate electrode 122s equivalent to the floating gate electrode 122 of the memory cell and a gate electrode 124s equivalent to the control gate electrode 124 of the memory cell are connected to each other at an opening formed in an intergate insulating film.

The N type diffusion layer 110 is shared by the memory cells M100 to M116 formed on the lower semiconductor layer 100 and adjacent memory cells. Thereby, the memory cells M100 to M116 formed on the lower semiconductor layer 100 are connected in series to each other. The selection gate transistor SG101 is disposed at one end of a series of the memory cells M100 to M116 connected in series to each other, and the selection gate transistor SG102 is disposed at the other end thereof. A cell string CS100 is formed of the series of memory cells M100 to M116 and the selection gate transistors SG101 and SG102 disposed at both ends of the series of memory cells M100 to M116. The cell string is a basic unit of the NAND-type nonvolatile memory. Usually, the number of memory cells included in the cell string is 16N (N is a natural number). In the embodiment, the number of memory cells M100 to M116 included in the cell string CS100 formed on the lower semiconductor layer 100 is equal to the number of memory cells M200 to M216 included in the cell string formed on the upper semiconductor layer 200. Then, in the embodiment, the number of memory cells included in the cell string formed on the lower semiconductor layer 100 is 16N+1 for a reason described later. In the embodiment, a case where the number of memory cells included in the cell string is 17 (when N=1) will be described for convenience of description.

The memory cells M100 to M116 and the selection gate transistors SG101 and SG102 formed on the lower semiconductor layer 100 are covered with the interlayer insulating film 140. The interlayer insulating film 140 has an opening 150 at an outer side of the selection gate transistor SG101 of the cell string CS200, and has an opening 160 at an outer side of the selection gate transistor SG102. The bit line plug 300 is formed in the opening 150 to contact the N type diffusion layer 110 of the selection gate transistor SG101 formed in the semiconductor layer 100 exposed from a bottom of the opening 150. Similarly, the source line plug 310 is formed in the opening 160 to contact the N type diffusion layer 110 of the selection gate transistor SG102 formed in the semiconductor layer 100 exposed from a bottom of the opening 160. The upper semiconductor layer 200 is formed on the interlayer insulating film 140.

The upper semiconductor layer 200 has a crystal defect 50a generated at a center of the upper semiconductor layer 200 between the opening 150 and the opening 160.

On the upper semiconductor layer 200, the memory cells M200 to M216 are formed. The memory cells M200 to M216 have the same structure as that of the memory cells M100 to M116 formed on the lower semiconductor layer 100. The selection gate transistors SG201 and SG202 have the same structures as that of the selection gate transistors SG101 and SG102 formed on the lower semiconductor layer 100. The N type diffusion layer 110 is shared by the plurality of memory cells M200 to M216 formed on the upper semiconductor layer 200 and adjacent memory cells. Thereby, the memory cells M200 to M216 formed on the upper semiconductor layer 200 are connected in series to each other. The selection gate transistor SG201 is disposed at one end of the series of the memory cells M200 to M216 connected in series to each other, and the selection gate transistor SG202 is disposed at the other end of the series of the memory cells M200 to M216. A cell string CS200 is formed of the series of the memory cells M200 to M216 and the selection gate transistors SG201 and SG202 disposed at both ends thereof.

The memory cells M200 to M216 formed in the upper semiconductor layer 200 is different from the memory cells formed in the lower semiconductor layer 100 in that the memory cell M208 among the memory cells M200 to M216 formed on the upper semiconductor layer 200 is disposed at the center and operates as a dummy cell, which is not used as a storage element. For this reason, the cell string CS200 formed on the upper semiconductor layer 200 includes 16 memory cells that operate as ordinary memory cells, and one memory cell that operates as a dummy cell. While the memory cell M208 that operates as a dummy cell has the same structure as that of other ordinary memory cells, the memory cell M208 operates differently from the ordinary memory cell. Here, operation of the ordinary memory cell means operation to change a threshold voltage of the memory cell and store 1 bit data or many bit data by changing a charged amount held in a floating gate electrode by write operation or erase operation. On the other hand, the memory cell M208 that operates as a dummy cell does not perform operation to hold the data, and performs operation to transmit an electron flowed in from an adjacent memory cell by use of a channel of the memory cell M208. This can be implemented by applying a certain voltage to the control gate electrode of the memory cell M208, for example. A reason why the memory cell that operates as a dummy cell is necessary and a reason why the memory cell that operates as a dummy cell is disposed at the center of the cell string will be described later.

The memory cells M200 to M216 formed in the upper semiconductor layer 200 and the selection gate transistors SG201 and SG202 are covered with an interlayer insulating film 240. The interlayer insulating film 240 has an opening 250 at an outer side of the selection gate transistor SG201 of the cell string CS200, and has an opening 260 at an outer side of the selection gate transistor SG202. The opening 250 is formed coaxial with the opening 150, and the opening 260 is formed coaxial with the opening 160. The bit line plug 300 and the source line plug 310 of the cell string CS200 formed in the upper semiconductor layer 200 are formed in the openings 250 and 260, respectively. The cell string CS100 formed on the lower semiconductor layer 100 and the cell string CS200 formed on the upper semiconductor layer 200 share the bit line plug 300 and the source line plug 310.

Here, a reason that a crystal defect 50a is generated in the upper semiconductor layer 200 will be described. In the case of a multilevel configuration of stacked memory cells, the upper semiconductor layer 200 in which the upper memory cells are formed is formed by epitaxial growth using the lower semiconductor layer 100, in which the lower memory cells are formed, as a seed crystal. Specifically, the lower semiconductor layer 100 in which the memory cells are formed is covered with the interlayer insulating film 140, the openings 150 and 160 are formed in the interlayer insulating film 140, and the lower semiconductor layer 100 is exposed. A silicon single crystal is epitaxially grown using the exposed lower semiconductor layer 100 as a seed crystal to form the upper semiconductor layer 200 on the interlayer insulating film 140. Here, when there are two openings 150 and 160, the crystal defect 50a is generated in a joint portion of the single crystal silicon epitaxially grown from each of the openings 150 and 160. The crystal defect 50a influences fluctuation in a degree of electron mobility and a way of expansion of a depletion layer in the channel. Accordingly, when the memory cell is formed on this crystal defect 50a, no desired property is obtained in this memory cell, so that the initial characteristic of the memory cell fluctuates. For this reason, the memory cell formed on the crystal defect 50a is not operated as the ordinary memory cell, and is operated as a dummy cell. This enables reduction in fluctuation in the initial characteristic of the memory cell.

When a growth rate of the single crystal silicon epitaxially grown from the opening 150 is equal to that of the single crystal silicon epitaxially grown from the opening 160, the crystal defect 50a is formed at the center of the upper semiconductor layer 200 between the opening 150 and the opening 160. Accordingly, the memory cell M208 at the center (hereinafter, “memory cell at the center” is referred to as “central memory cell”) is operated as a dummy cell among the memory cells formed on the upper semiconductor layer 200.

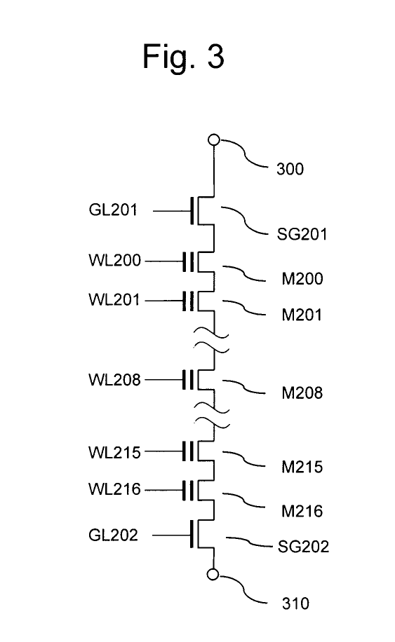

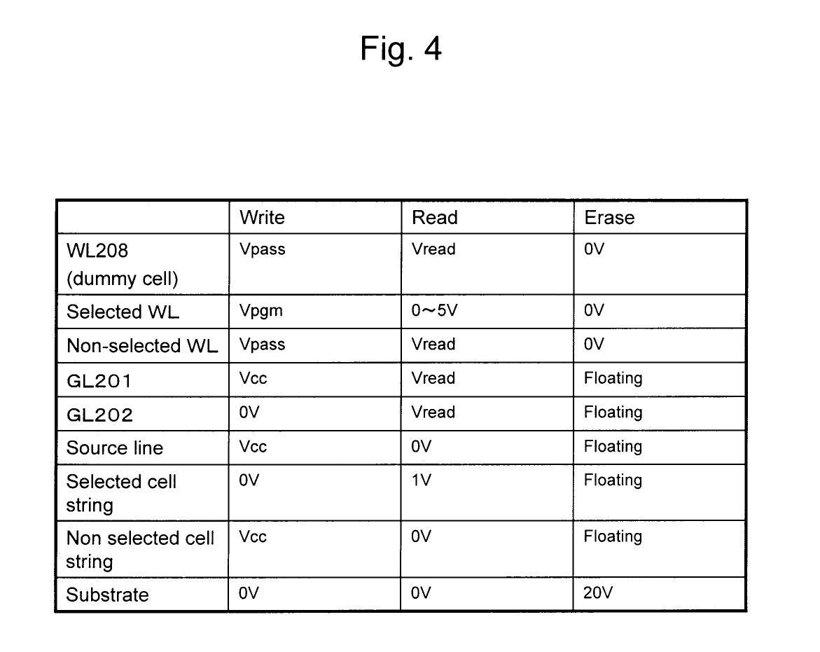

Next, operation of the memory cell M208 that operates as a dummy cell at the time of data write operation when the cell string CS200 is a non-selection cell string will be described with reference to FIG. 3 and FIG. 4. FIG. 3 is an equivalent circuit diagram of the cell string CS200 according to the embodiment. FIG. 4 shows a chart showing conditions of write, read, and erase voltage of the cell string CS200 according to the embodiment.

When the cell string CS200 is a non-selection cell string, a supply voltage Vcc is applied to the bit line plug 300 so that the data may not be written into the memory cells M200 to M216 at the time of the data write operation. At the time of the data write operation, a write voltage Vpgm is applied to a word line to be written into (for example, WL201), and a transfer voltage Vpass is applied to the remaining word lines WL200 to WL216 (except WL201). At this time, the transfer voltage Vpass (approximately 4 V to 12 V) is applied to the word line WL208 of the memory cell M208 that operates as a dummy cell. The supply voltage Vcc is applied to the selection gate line GL201, and the ground voltage 0V is applied to the selection gate line GL202. The word lines WL200 to WL216 (except WL208) sequentially become a word line to be written into. Thereby, the transfer voltage Vpass and the write voltage Vpgm are applied to the word lines WL200 to WL216 (except WL208). On the other hand, the Vpgm is not applied to the word line WL208 of the memory cell M208 that operates as a dummy cell. Thereby, at the time of the write operation, the memory cell M208 that operates as a dummy cell does not perform the operation to hold the data, but the channel thereof performs the operation to transmit the electron flowed in from an adjacent memory cell.

At the time of the read operation, a read voltage Vread (approximately 3 to 7 V) applied to the non-selection word line is applied to the word line WL208 of the memory cell M208 that operates as a dummy cell. Thereby, at the time of the read operation, the channel of the memory cell M208 that operates as a dummy cell performs the operation to transmit the electron flowed in from an adjacent memory cell. At the time of the erase operation, a ground voltage 0 V is applied to the word line WL208 of the memory cell M208 that operates as a dummy cell.

As mentioned above, as a characteristic of the first embodiment according to the present invention, the memory cell M208 located on the crystal defect 50a and disposed at the center of the series of the memory cells M200 to M216 formed on the upper semiconductor layer 200 operates as a dummy cell. The memory cell formed on the crystal defect 50a generated in the upper semiconductor layer 200 is operated as a dummy cell not used as a storage element, thereby allowing reduction in fluctuation in the initial characteristic of the memory cell.

Moreover, because the memory cell M208 disposed on the crystal defect 50a is operated as a dummy cell, the channel of the memory cell M208 can be disposed on the crystal defect 50a. In order to suppress the influence of the crystal defect, in the related art, the source/drain of the memory cell needs to be formed so as to be disposed on the crystal defect, and high accuracy in alignment of the source/drain with the crystal defect is demanded. In the case of the embodiment, because the memory cell M208 disposed on the crystal defect 50a operates as a dummy cell, the channel of the memory cell M208 and the N type diffusion layer 110 may be formed so as to be disposed on the crystal defect. For this reason, the alignment accuracy may be lower than that in the related art.

In the embodiment, description has been given of the case where the silicon single crystal epitaxially grows from the opening 150 at the same growth rate as the silicon single crystal epitaxially grows from the opening 160, and the crystal defect 50a is formed at the center of the upper semiconductor layer 200 between the opening 150 and the opening 160 in formation of the upper semiconductor layer 200. However, the present invention will not be limited to such a case. When the growth rate of the silicon single crystal epitaxially grown from the opening 150 is different from that of the silicon single crystal epitaxially grown from the opening 16 and a position of the crystal defect to be generated is expected in advance at a stage of design and the like, the memory cell formed on this crystal defect can also be configured to operate as a dummy cell. In this case, the memory cell that operates as a dummy cell is not always the central memory cell M208 of the cell string CS200 formed on the upper semiconductor layer 200.

### Embodiment 2

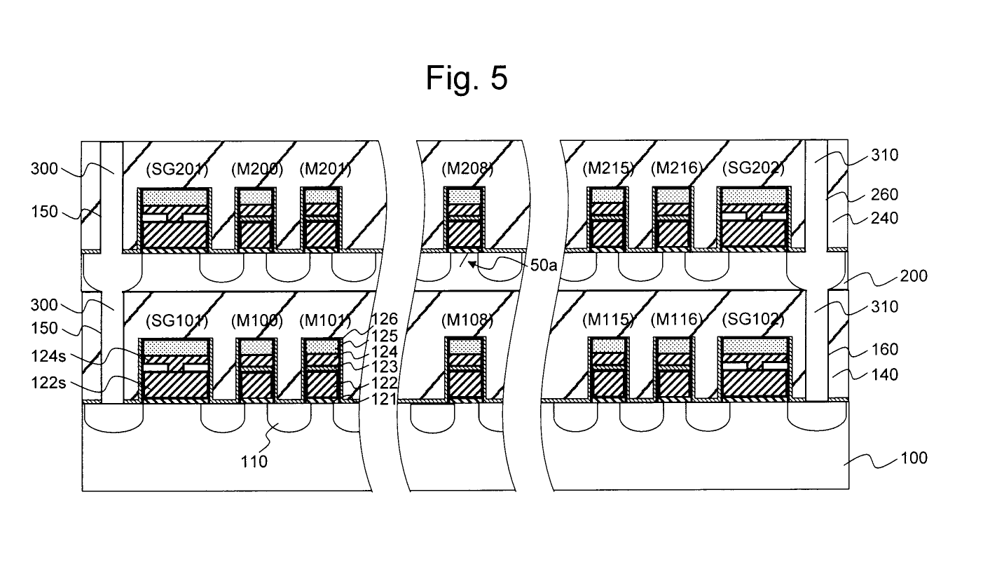

FIG. 5 is a sectional view of a NAND-type nonvolatile memory according to a second embodiment in a direction of a bit line. A plan view of a memory cell array of the NAND-type nonvolatile memory according to the second embodiment is omitted because the plan view is the same as that of the NAND-type nonvolatile memory according to the first embodiment. The same reference numerals will be given to the same components as those of the first embodiment, and description thereof will be omitted.

Similarly to the case of the NAND-type nonvolatile memory according to the first embodiment of the present invention, the NAND-type nonvolatile memory according to the second embodiment of the present invention operates the central memory cell M208 of the cell string CS200 formed on the upper semiconductor layer 200 as a dummy cell. Thereby, the same effect as that in embodiment 1 is obtained.

The NAND-type nonvolatile memory according to the second embodiment of the present invention is different from the NAND-type nonvolatile memory according to the first embodiment of the present invention in that the central memory cell M108 of the cell string CS100 formed on the lower semiconductor layer 100 is operated as a dummy cell. No crystal defect is generated at the center of the lower semiconductor layer 100 as in the upper semiconductor layer 200. However, the following effects are obtained by operating the central memory cell M108 of the cell string CS100 formed in the lower semiconductor layer 100 as a dummy cell.

As mentioned above, a cell string is a basic unit of the NAND-type nonvolatile memory. For this reason, preferably, all the cell strings have the same configuration when the memory cells of the NAND-type nonvolatile memory are driven by an external circuit. All the cell strings having the same configuration can use the same peripheral circuits such as a decoder in all the cell strings.

In the configuration of the first embodiment according to the present invention, the cell string CS100 formed on the lower semiconductor layer 100 includes 16N+1 of the memory cells that operate as the ordinary memory cells. On the other hand, the cell string CS200 formed on the upper semiconductor layer 200 includes 16N of the memory cells that operate as the ordinary memory cells and one memory cell that operates as a dummy cell at the center of the cell string CS200. Thus, for the above-mentioned reason, it is not preferable that the configuration of the cell string CS100 formed on the lower semiconductor layer 100 is different from the configuration of the cell string CS200 formed on the upper semiconductor layer 200.

Then, in the embodiment, the central memory cell of the cell string formed on the lower semiconductor layer 100 is operated as a dummy cell, and thereby the configuration of the cell string CS200 formed on the upper semiconductor layer 200 is the same as that of the cell string CS100 formed on the lower semiconductor layer 100. Accordingly, the cell strings CS100 and CS200 can share circuits such as peripheral circuits.

When the growth rate of the silicon single crystal epitaxially grown from the opening 150 is different from that of the silicon single crystal epitaxially grown from the opening 16, and the crystal defect 50a is formed at a place other than the center of the upper semiconductor layer 200 between the opening 150 and the opening 160, the memory cell formed on this crystal defect can also be configured to operate as a dummy cell, if a position of the crystal defect to be generated is expected in advance at a stage of design and the like. In this case, the memory cell on the lower semiconductor layer 100 corresponding to the memory cell that operates as a dummy cell on the upper semiconductor layer 200 is operated as a dummy cell. Here, “corresponding” means that a place of the memory cell disposed on the memory string is the same. For example, when the eighth memory cell M207 from the bit line plug 300 of the cell string CS200 on the upper semiconductor layer 200 is operated as a dummy cell, the memory cell on the lower semiconductor layer 100 corresponding to the memory cell M207 is the eighth memory cell M107 from the bit line plug 300 of the cell string CS100 on the lower semiconductor layer 100.

### Embodiment 3

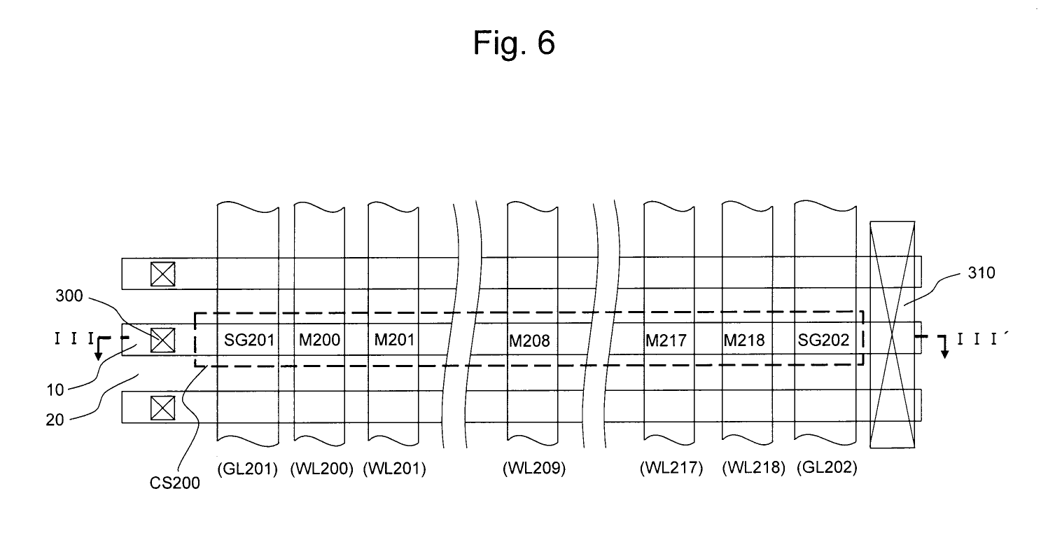

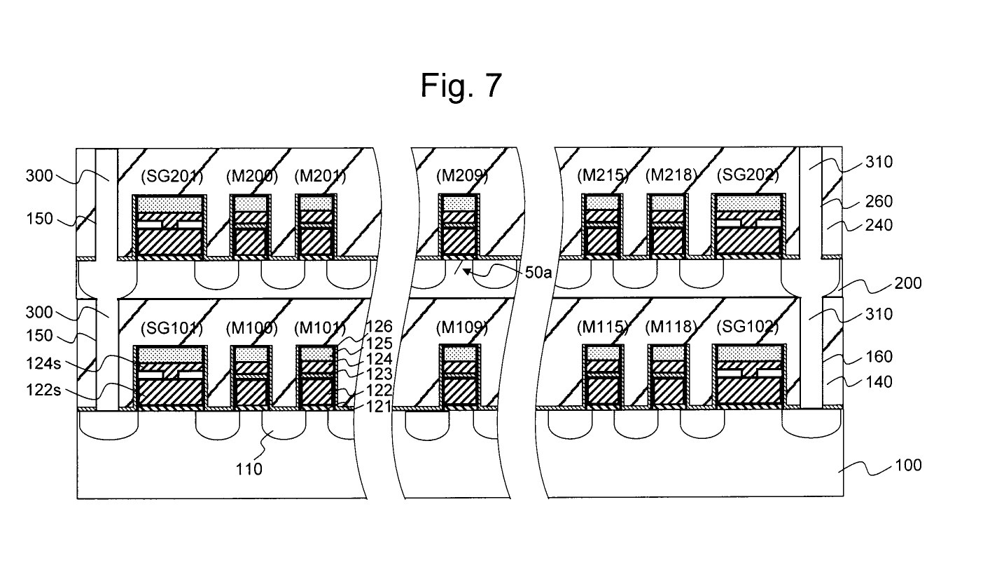

FIG. 6 is a plan view of a memory cell array of a NAND-type nonvolatile memory according to a third embodiment. FIG. 7 is a sectional view of the NAND-type nonvolatile memory according to the third embodiment in a direction of a bit line (a sectional view taken along the line III-III' in FIG. 6). The same reference numerals will be given to the same components as those of the first embodiment, and description thereof will be omitted. In the embodiment, the number of memory cells included in each of the cell string SC100 formed in the lower semiconductor layer 100 and the cell string SC200 formed in the upper semiconductor layer 200 is 19 as will be described later. Then, the memory cells disposed at the center of the cell string SC100 and at the center of the cell string SC200 are M109 and M209, respectively.

The NAND-type nonvolatile memory according to the third embodiment of the present invention has a dummy cell M109 disposed at the center of the cell string SC200 formed on the upper semiconductor layer 200 similarly to the cases of the NAND-type nonvolatile memory according to the first and second embodiments of the present invention. Thereby, the same effect as that in embodiment 1 is obtained.

In the cell string SC100 formed in the lower semiconductor layer 100, all the memory cells may operate as the ordinary memory cells as in the first embodiment, and the central memory cell M109 may operate as a dummy cell as in the second embodiment. In the embodiment, a case where M109 is a dummy cell will be described.

The NAND-type nonvolatile memory according to the third embodiment of the present invention is different from the NAND-type nonvolatile memory according to the first and the second embodiment of the present invention in that the memory cells (M100, M118) adjacent to the selection gate transistors SG101 and SG102 among the memory cells M100 to M118 formed on the lower semiconductor layer 100 are operated as a dummy cell. Similarly, the memory cells (M200, M218) adjacent to the selection gate transistors SG201 and SG202 among the memory cells M200 to M218 formed on the upper semiconductor layer 200 are operated as a dummy cell. In accordance with such a configuration, the memory cells formed on the lower semiconductor layer 100 include 8N of the memory cells that operate as the ordinary memory cell, and three memory cells that operate as a dummy cell, and 8N+3 in total. The memory cells formed on the upper semiconductor layer 200 include 8N of the memory cells that operate as the ordinary memory cell, and three memory cells that operate as a dummy cell, and 8N+3 in total.

As known, Gate Induced Drain Leakage (GIDL) current might flow at an edge of each of the selection gate transistors SG101, SG102, SG201, and SG202, and erroneous write may occur in the non-selection memory cell adjacent to the selection gate transistor. In the embodiment, by operating M100, M118 and M200, and M218 as dummy cells, the selection gate transistors SG101, SG102, SG201, and SG202 can be kept apart from the adjacent memory cells M101, M117, M201, and M217 that operate as the ordinary memory cells, respectively. As a result, the GIDL current at an edge of the selection gate transistor can be suppressed to reduce erroneous write.

Each of the above-mentioned embodiments is given for the purpose of facilitating the understanding of the present invention, and not of limiting the invention. Therefore, various changes and modifications are possible without departing from the scope of the invention, while the present invention also encompasses the equivalents thereof. For example, in each embodiment of the present invention, the NAND-type nonvolatile memory of a two-level configuration formed of the upper semiconductor layer and the lower semiconductor layer has been described. However, the present invention is not limited to the NAND-type nonvolatile memory of the two-level configuration, but may be the NAND-type nonvolatile memory of a configuration of a three-level or more. In this case, the memory cell disposed at the center of the cell string formed on each semiconductor layer at the two-level or more is operated as a dummy cell.

Moreover, in the embodiment, description has been given of the case where the silicon single crystal grows epitaxially from the opening 150 at the same growth rate as the silicon single crystal grows epitaxially from the opening 160, and the crystal defect 50a is formed at the center of the upper semiconductor layer 200 between the opening 150 and the opening 160 in formation of the upper semiconductor layer 200. However, the present invention will not be limited to such a case, and includes the case in which, when the growth rate of the silicon single crystal epitaxially grown from the opening 150 is different from that of the silicon single crystal epitaxially grown from the opening 16 and a position of the crystal defect to be generated is expected in advance at a stage of design, the memory cell formed on this crystal defect can also be configured to operate as a dummy cell.

1. A nonvolatile semiconductor memory, comprising:
a lower semiconductor layer;
a first cell string having a plurality of memory cells formed on the lower semiconductor layer;
a upper semiconductor layer formed on the lower semiconductor layer with an interlayer insulating film interposed therebetween; and
a second cell string having a plurality of memory cells formed on the upper semiconductor layer; wherein
a memory cell formed on a crystal defect in the upper semiconductor layer is a dummy cell.

2. The nonvolatile semiconductor memory according to claim 1, wherein the dummy cell is a memory cell disposed at a center of the second cell string.

3. The nonvolatile semiconductor memory according to claim 1, wherein a memory cell formed on the lower semiconductor layer which is corresponding the dummy cell is a dummy cell.

4. The nonvolatile semiconductor memory according to claim 1, wherein the dummy cell has the same structure as the memory cells.

5. The nonvolatile semiconductor memory according to claim 1, wherein the dummy cell is operated as dummy cell at the time of data write operation and read operation.

6. The nonvolatile semiconductor memory according to claim 1, wherein the dummy cell is applied a certain voltage to the control gate electrode at the time of data write operation and read operation.

7. The nonvolatile semiconductor memory according to claim 1, wherein the upper semiconductor layer is formed by epitaxial growth.

8. A nonvolatile semiconductor memory, comprising:
a lower semiconductor layer;
a first cell string having a plurality of memory cells formed on the lower semiconductor layer;
a upper semiconductor layer formed on the lower semiconductor layer with an interlayer insulating film interposed therebetween; and
a second cell string having a plurality of memory cells formed on the upper semiconductor layer; wherein
the second cell string includes 16N+1 of memory cells.

9. The nonvolatile semiconductor memory according to claim 8, wherein the first cell string includes 16N+1 of memory cells.

10. The nonvolatile semiconductor memory according to claim 8, wherein the upper semiconductor layer has a crystal defect, and a memory cell formed on a crystal defect is a dummy cell.
